(19) United States
(12) Patent Application Publication
(10) Pub. No.: US 2010/0051324 A1
(43) Pub. Date: Mar. 4, 2010

(54) DIELECTRIC SUBSTRATE WITH HOLES AND METHOD OF MANUFACTURE

(76) Inventors: Vincent Yong Chin Lee, Singapore (SG); Yi Liang Fu, Singapore (SG); Tatsunori Koyanagi, Tokyo (JP); Yoshiyuki Ohkura, Tokyo (JP); Masahiko Ito, Tokyo (JP)

Correspondence Address: 3M INNOVATIVE PROPERTIES COMPANY, PO BOX 33427, ST. PAUL, MN, 55133-3427, US

(21) Appl. No.: 11/917,445

(22) PCT Filed: Jun. 20, 2006
(86) PCT No.: PCT/US06/23832

§ 371 Date: Nov. 16, 2009

(30) Foreign Application Priority Data
Jun. 22, 2005 (SG) 200504031-6

(51) Int. Cl. H05K 1/02; G03F 7/20

(52) U.S. Cl. 174/251; 430/323; 174/261

(57) ABSTRACT

An aspect of the present invention comprises a method of forming holes in a dielectric substrate comprising the steps of applying a layer of photoresist to a dielectric substrate, exposing portions of the photoresist to actinic radiation through a photomask to form a pattern in the photoresist for an array of holes to be etched in the substrate, developing the photoresist, etching the dielectric substrate to form an array of holes, each hole extending at least partially through the dielectric substrate, and removing the excess photoresist. Another aspect of the present invention is a method of simultaneously forming holes in a dielectric substrate some of which extend partially through the substrate and some of which extend completely through the substrate. Other aspects of the present invention are dielectric substrates formed using the methods of the invention.

### FIELD

The invention relates to the manufacture of dielectric substrates with holes using controlled chemical etching techniques.

### BACKGROUND

With the market trend moving towards developing smaller, more compact and increased functionality devices, the amount of space within the enclosures of such devices for the placement of internal components such as power source, flexible circuit, among others, is reduced.

Flexible circuits are circuits that are formed on flexible dielectric substrates. The circuits may have one or more conductive layers as well as circuitry on one or both of the major surfaces. The circuits often include additional functional layers, insulating layers, adhesive layers, encapsulating layers, stiffening layers, among others. Flexible circuits are typically useful for electronic packages where flexibility, weight control and the like are important. In many high volume situations, flexible circuits also provide cost advantages associated with efficiency of the manufacturing process employed.

To maximise the use of space within each device enclosure, much effort is put into the design of the device including the layout and placement of the internal components within the enclosure. This creates a need for the flexible circuit to be able to be easily folded at pre-defined locations and for the flexible circuit to be able to retain its folded position by itself without the use of additional devices. It is important that the substrate folds only at pre-defined locations so as to prevent unnecessary creases on the flexible circuit when the internal components are positioned as the device is assembled which may then cause the flexible circuit to fail prematurely.

FIG. 1 is a cross section showing an example of how a flexible circuit 10 may be mounted on a display panel. For simplicity, the illustration identifies the flexible circuit 10 as a whole and does not represent the various components of the flexible circuit separately. FIG. 1 shows a flexible circuit 10 being folded at corners 15 having the display panel 35 attached on one end and an electronic component 30 driving the display panel on the other end. An example of an electronic component 30 is a printed circuit board. Between the flexible circuit 10 and the heat sink 20 which are placed in parallel is a small air gap 25. In this example, if the flexible circuit 10 is to be bent and positioned as shown in FIG. 1, it is desired that the bending angle at the corners 15 be about 90 degrees. A flexible circuit 10 when folded as such will maintain its position and therefore, the flexible circuit 10 is less likely to come into contact with the heat sink 20. An improperly folded flexible circuit 10 is less likely to retain its folded position and has a high tendency to warp thereby moving into the air gap 25 and coming into contact with the heat sink 20 as shown in FIG. 2. This may result in the premature failure of the flexible circuit 10.

In the absence of a heat sink 20, an improperly folded flexible circuit 10, which is less likely to retain its folded position and has a high tendency to warp, may also prematurely fail due to vibration, abrasion, static discharge, or other forces when it comes into contact with other internal components within the enclosure or the enclosure casing itself. The other components within the casing or the casing may serve as the source of the vibration, abrasion, static discharge, or other forces.

One way of increasing the ease of folding of a flexible circuit at a pre-defined location is to reduce the amount of substrate at that location. FIG. 3 shows a substrate 100 which is for example of 50 microns thick, where 25 microns of the thickness is removed at the folding location 60. In FIG. 4, a load 65 is applied to the centre of the folding location 60 as the fulcrum, allowing the substrate 100 to be folded easily.

Japanese Patent Application No. 91450 describes a film carrier having the thickness of its insulating base material at the bending location reduced by irradiation with an excimer laser to cleave the bonds between the molecules of the base material by means of photochemical ablation process.

There are at least three problems associated with the method described in the Japanese patent application. First, the use of a laser beam device to reduce the thickness of the substrate at the bending location is an additional process step in the manufacture of the flexible circuit. Second, slits created using laser beams tend to have very sharp corners at the trough. These corners are high pressure points that generate high stress which then may cause the substrate to crack at the corners when the substrate is bent. One way of reducing the stress at the corners, thereby reducing the likelihood of cracks developing at the corners, is to widen the breadth of the slits resulting in the creation of slots. As the stress generated is distributed across the breadth, there is a lesser tendency for the substrate to crack. However, this excavation of slots adds considerable time to the manufacturing process resulting in a loss of productivity. Third, the substrate fragments may spatter during the laser etching process thereby contaminating the surface of the substrate which necessitates an additional cleaning step in the flexible circuit manufacturing process. The use of a laser to reduce the substrate thickness and the addition of the cleaning step in the manufacturing process to remove substrate fragments are expensive and add costs to the manufacturing process.

Japanese Patent No. 3327252 describes the formation of a grid of zigzag-like mesh holes in the bending location by a punching press-work using a metallic mould. In this case, a grid of holes is punched through the substrate to form the bending location prior to the flexible circuit manufacturing process. FIG. 5 illustrates the flexible circuit at the end of the manufacturing process. In the figure, hole 70 is a hole that has been punched in the substrate 100, adhesive 40 bonds the substrate 100 to the copper wiring 45 and a layer of liquid polymer 55 protects the surface of the copper wiring 45. Copper wiring 45 is exposed by the hole punching process. A layer of solder resist 50 is usually applied to protect the copper wiring 45 on the major surface opposite hole 70. The liquid polymer 55 needs to be flexible so as to prevent cracking during bending. Liquid polymer 55 also needs to be applied selectively to coat the inside of the hole 70 and a curing step is needed after coating which complicates the manufacturing process. There is also a risk that the liquid polymer 55 may peel from the copper wiring 45 under extreme bending conditions.

The manufacturing process for flexible circuits involves many steps and for some steps, such as flexible circuit inspection, it is necessary to have completely etched through holes on the substrate. These through holes are also needed after the flexible circuits are manufactured and when the flexible circuits are adopted for use on the devices for which they are made. The through holes serve as sprocket holes or tooling holes depending on when they are used and the purpose for which they are used.

### SUMMARY OF THE INVENTION

In broad terms in one aspect the invention comprises a method of forming holes in a dielectric substrate comprising the steps of applying a layer of photoresist to a dielectric substrate, exposing portions of the photoresist to actinic radiation through a photomask to form a pattern in the photoresist for an array of holes to be etched in the substrate, developing the photoresist, etching the dielectric substrate to form an array of holes, each hole extending at least partially through the dielectric substrate, and removing the excess photoresist.

In broad terms in another embodiment the invention comprises a method of forming holes in a dielectric substrate comprising the steps of: applying a layer of photoresist to a dielectric substrate, exposing portions of the photoresist to actinic radiation through a photomask to form a pattern in the photoresist for a plurality of holes comprising at least one array of holes to be etched in the substrate, developing the photoresist, etching the dielectric substrate to form an array of holes extending partially through the dielectric substrate and at least one hole extending completely through the dielectric substrate, and removing the excess photoresist.

In at least one embodiment the method further includes the steps of providing a photomask comprising an array of distinct dots, exposing portions of the photoresist to actinic radiation through the photomask, etching the dielectric substrate to form an array of holes, wherein the size and/or the pitch of the dots on the photomask are selected so that at least two of the holes formed in the dielectric substrate after etching are connected.

In broad terms in another embodiment the invention comprises a dielectric substrate comprising at least one array of holes partially etched into the dielectric substrate, wiring formed on the dielectric substrate, and solder resist layered over the wiring to protect the wiring.

In broad terms in another embodiment the invention comprises a dielectric substrate comprising at least one array of holes partially etched into the dielectric substrate, at least one hole etched completely through the dielectric substrate, wiring formed on the dielectric substrate, and solder resist layered over the wiring to protect the wiring.

In at least one embodiment the dielectric substrate is flexible.

In at least one embodiment at least two holes in the array of holes are connected after being etched.

In at least one embodiment the array of holes is arranged to form a fold guide in the dielectric substrate.

In at least one embodiment the thickness of the etched portion of the fold guide substrate is about 80% of the unetched dielectric substrate thickness.

In at least one embodiment the dielectric substrate is formed from polyimide.

In at least one embodiment the dielectric substrate may further comprise at least one integrated circuit.

### BRIEF DESCRIPTION OF DRAWINGS

The invention will be further described by way of example only and without intending to be limiting with reference to the following drawings, wherein:

FIG. 1 shows an example of a substrate mounted on a display panel;

FIG. 2 shows an example of a improperly folded flexible circuit mounted on a display panel that has warped because of the display panel departing from its original placement as a consequence of the flexible circuit being unable to maintain its folded position;

FIG. 3 shows an example of a substrate having a portion of the substrate removed at a pre-defined location;

FIG. 4 shows an example of a substrate folded as a result of a load applied at the centre of the trough at a pre-defined location;

FIG. 5 shows an example of a flexible circuit obtained using the process described in the Japanese Patent No. 3327252;

FIG. 6A shows a first example of a photomask designed to provide a pattern for an array of holes in the photoresist;

FIG. 6B is a top view of a fold guide in a substrate with partial holes created after etching using the photomask of FIG. 6A;

FIG. 6C is a cross-section of a substrate with unconnected partial holes created using the photomask of FIG. 6A;

FIG. 7A shows a second example of a photomask designed to provide a pattern for an array of holes in the photoresist;

FIG. 7B is a top view of a fold guide in a substrate with partial holes created after etching using the photomask of FIG. 7A;

FIG. 7C is a cross-section of a substrate with connected partial holes created using the photomask of FIG. 7A;

FIG. 8A shows a third example of a photomask designed to provide patterns for different arrays of holes of different sizes and of different spacing between holes in the photoresist;

FIG. 8B is a cross-section of a substrate with unconnected partial holes, connected partial holes, and unconnected through holes, created using the photomask of FIG. 8A;

FIG. 9A shows a first step in forming a partial hole in a substrate of the invention;

FIG. 9B shows a second step in forming a partial hole in a substrate of the invention;

FIG. 9C shows a third step in forming a partial hole in a substrate of the invention;

FIG. 9D shows a fourth step in forming a partial hole in a substrate of the invention; and

FIG. 10 shows an array of holes formed by selectively etching one embodiment of substrate of the invention using a chemical etchant to create a fold guide in a substrate.

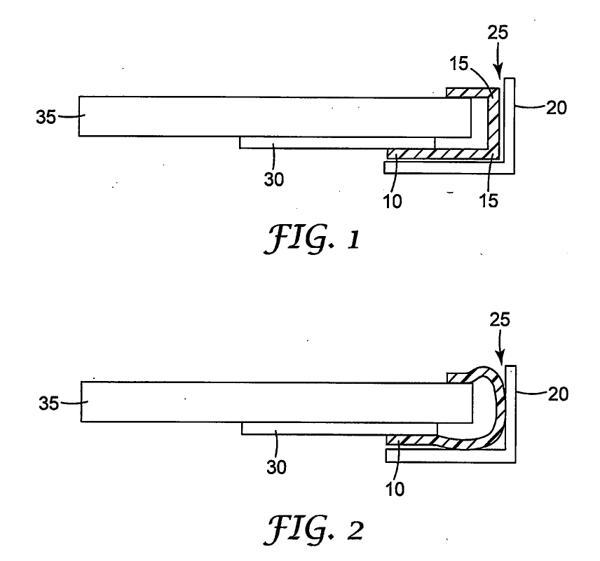

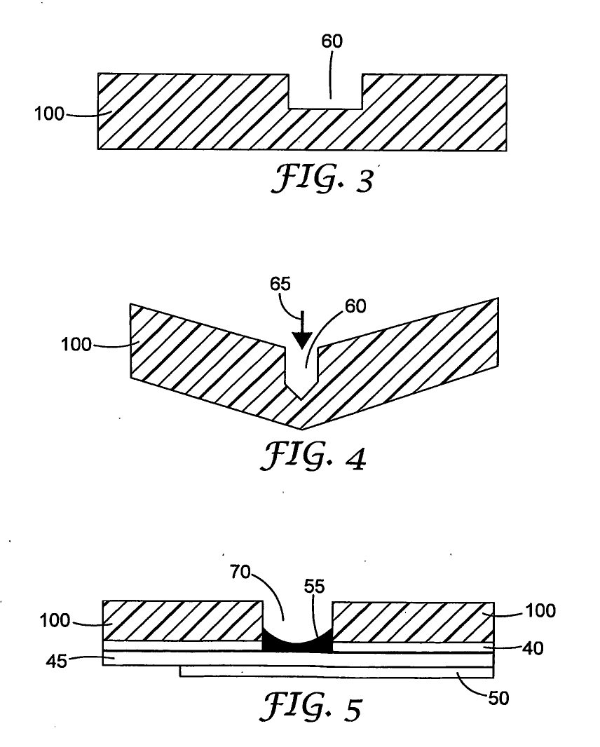

### DETAILED DESCRIPTION

Circuits may be made by a number of suitable methods such as subtractive, additive-subtractive, and semi-additive.

In a typical subtractive circuit-making process, a substrate usually having a thickness of about 10 microns to about 150 microns is first provided.

The substrate serves to insulate the conductors from each other and provides much of the mechanical strength of the circuit. Other attributes of the substrate include flexibility, thinness, high temperature performance, etchability, size reduction, weight reduction, among others.

Many different materials may be used as substrates for flexible circuit manufacture. The substrate choice is dependent on a combination of factors including economics, end-product application and assembly technology to be used for components on the finished product.

The substrate may be any suitable polyimide including, but not limited to, those available under the trade name APICAL, including APICAL NPI from Kaneka High-Tech Materials, Inc., Pasadena, Tex. (USA); and those available under the trade names KAPTON, including KAPTON E, KAPTON EN, KAPTON H, and KAPTON V from DuPont High Performance Materials, Circleville, Ohio (USA).

Other polymers such as liquid crystal polymer (LCP), available from Kuraray High Performance Materials Division, Osaka (Japan); poly(ethylene terephthalate) (PET) and poly(ethylene naphthalate) (PEN), available under trade names of MYLAR and TEONEX respectively from DuPont Tiejin Films, Hopewell, Va. (USA); and polycarbonate available under trade name of LEXAN from General Electric Plastics, Pittsfield, Mass. (USA), among others, may be used.

Preferably the substrate is a polyimide. Desirably the dielectric substrate is flexible.

The substrate may first be coated with a tie layer. After a tie layer is deposited, a conductive layer may be deposited by known methods such as vapour deposition or sputtering. Optionally, the deposited conductive layer(s) can be plated up further to a desired thickness by known electroplating or electroless plating processes.

The conductive layer can be patterned using a number of well-known methods including photolithography. If photolithography is used, photoresists, which may be aqueous or solvent based, and may be negative or positive photoresists, are then laminated or coated on at least the metal-coated side of the substrate using standard laminating techniques with hot rollers or any number of coating techniques (e.g. knife coating, die coating, gravure roll coating, etc.). The thickness of the photoresist ranges from about 1 micron to about 100 microns. The photoresist is then exposed to actinic radiation, for example ultraviolet light or the like, through a photomask or phototool. For a negative photoresist, the exposed portions are crosslinked and the unexposed portions of the photoresist are then developed with an appropriate solvent.

The exposed portions of the conductive layer are etched away using an appropriate etchant. Then the exposed portions of the tie layer are etched away using a suitable etchant. The remaining (unexposed) conductive metal layer preferably has a final thickness ranging from about 5 microns to about 70 microns. The crosslinked resist is then stripped off the laminate in a suitable solution. The conductive layer may form wiring on the substrate. The wiring may be plated with solder resist to protect the wiring.

If desired, the substrate may be etched to form features in the substrate. Subsequent processing steps, such as application of a covercoat or solder resist and additional plating may then be carried out. Integrated circuits can also be provided on the substrate.

Another possible method of forming the circuit portion would utilize semi-additive plating and the following typical step sequence:

A substrate may be coated with a tie layer. A thin first conductive layer may then be deposited using a vacuum sputtering or an evaporation technique. The materials and thicknesses of the substrate and conductive layer may be the same as those described in the previous paragraphs.

The conductive layer can be patterned in the same manner as described above in the subtractive circuit-making process. The first exposed portions of the conductive layer(s) may then be further plated using standard electroplating or electroless plating methods until the desired circuit thickness in the range of about 5 microns to about 70 microns is achieved.

The cross-linked exposed portions of the resist are then stripped off. Subsequently, the exposed portions of the thin first conductive layer(s) is/are etched with an etchant that does not harm the substrate. If the tie layer is to be removed where exposed, it can be removed with appropriate etchants. The remaining conductive layer may form wiring on the substrate.

If desired the substrate may be etched to form features in the substrate. Subsequent processing steps, such as application of a covercoat or solder resist, and additional plating may then be carried out. The substrate may further be provided with one or more integrated circuits.

Another possible method of forming the circuit portion would utilise a combination of subtractive and additive plating, referred to as a subtractive-additive method, and the following typical step sequence:

A substrate may be coated with a tie layer. A thin first conductive layer may then be deposited using a vacuum sputtering or evaporation technique. The materials and thicknesses for the dielectric substrate and conductive layer may be as described in the previous paragraphs.

The conductive layer can be patterned by a number of well-known methods including photolithography, as described above. When the photoresist forms a positive pattern of the desired pattern for the conductive layer, the exposed conductive material is typically etched away using a suitable etchant. The tie layer is then etched with a suitable etchant. The exposed (crosslinked) portion of the resist is then stripped. The desired conductive layer thickness can then be achieved with additional plating to a final thickness of about 5 microns to 70 microns.

If desired the substrate may be etched to form features in the substrate. Subsequent processing steps, such as application of a covercoat or solder resist and additional plating may then be carried out.

It should be noted that the figures in this specification are not drawn to scale. The figures are drawn to explain the concept and/or illustrate the invention and should not be interpreted as scale drawings. It should also be noted that most of the figures represent cross sections of articles that are three dimensional. The cross sections may sometimes be used to illustrate the different layers of a flexible circuit.

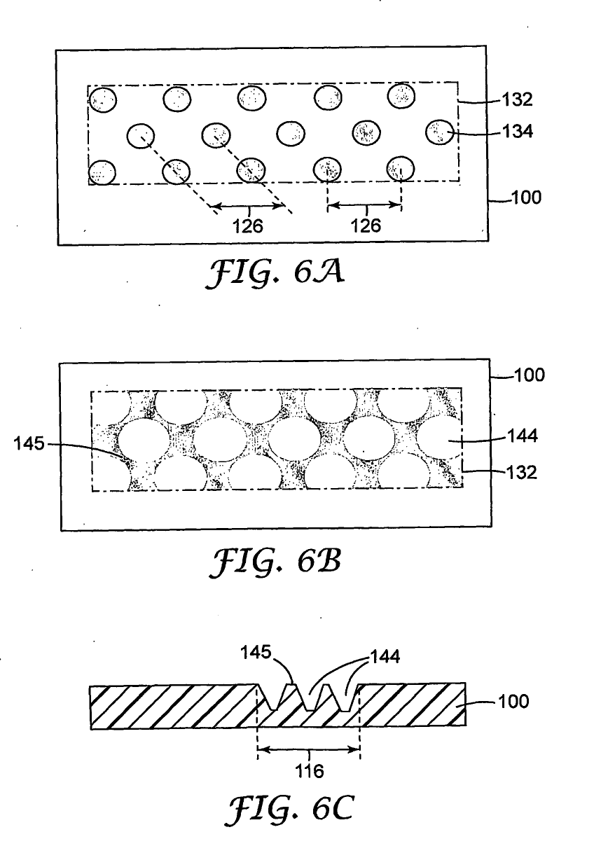

FIG. 6A shows a photomask 132 with an array of dots 134. Dots 134 are separated by pitch 126 on the photomask. The arrangement of dots 134 on photomask 132 is designed to provide a pattern for a corresponding array of holes in the photoresist applied to a dielectric substrate. The photoresist is exposed to actinic radiation through the photomask to pattern the holes into the photoresist. The photoresist is then developed to expose areas of the dielectric substrate to be etched using known etching techniques. The above photomask design is for use with negative photoresist and a reverse contrast in photomask will be required for use with positive photoresist.

FIG. 6B is a top view of a dielectric substrate 100 after holes have been partially etched in the substrate using the photomask 132 shown in FIG. 6A. An outline of photomask 132 is provided in FIG. 6B for convenience but it is well understood in practice that the photomask will not be present on the substrate of FIG. 6B. As can be seen in FIG. 6B partial holes 144 have been etched into dielectric substrate 100 by the etching process. Partial holes 144 are centred in the same positions as dots 134 on the photomask. However partial holes 144 have a wider circumference than dots 134 due to the etching process. Due to the pitch 126 and/or size of the dots on the photomask (shown in FIG. 6A) once the partial holes 144 have been etched some areas of dielectric substrate 145 between the partial holes are not etched.

FIG. 6C is cross-sectional view of part of substrate 100 showing partial holes 144 formed in the dielectric substrate. In this view the partial holes 144 can clearly be seen as can unetched areas 145 between the partial holes. If the partial holes 144 are etched to form a fold guide in dielectric substrate 100 then width 116 defines the width of the folding portion of the fold guide. This width can be altered by altering the number of rows of dots and/or the size of the dots on photomask 132 (shown in FIG. 6A).

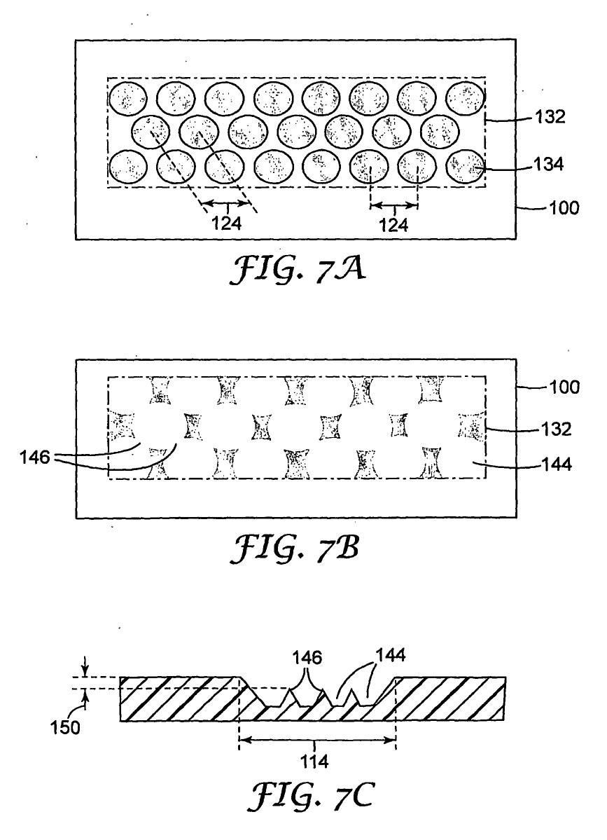

FIG. 7A shows a photomask 132 with an array of dots 134. Dots 134 are separated by pitch 124 on the photomask. The arrangement of dots 134 on photomask 132 is designed to provide a pattern for a corresponding array of holes in photoresist applied to a dielectric substrate. The photoresist is exposed using the photomask to pattern the holes into the photoresist. The photoresist is then developed to expose areas of the dielectric substrate to be etched using known etching techniques. Again, the above photomask design is for use with negative photoresist and a reverse contrast in photomask will be required for use with positive photoresist.

FIG. 7B is a top view of a dielectric substrate 100 after holes have been partially etched in the substrate using the photomask 132 shown in FIG. 7A. An outline of photomask 132 is provided in FIG. 7B for convenience but it is well understood in practice that the photomask will not be present on the substrate of FIG. 7B. As can be seen in FIG. 7B partial holes 144 have been etched into dielectric substrate 100 by the etching process. Partial holes 144 are centred in the same positions as dots 134 on the photomask. However partial holes 144 have a wider circumference than dots 134 due to the etching process. Due to the pitch 124 and/or size of the dots on the photomask (shown in FIG. 7A) once the partial holes 144 have been etched areas of dielectric substrate 100 between the partial holes are also etched.

FIG. 7C is cross-sectional view of part of substrate 100 showing partial holes 144 formed in the dielectric substrate. In this view the partial holes 144 can clearly be seen as can the etched areas between the partial holes. Portions 146 between the holes are partially etched to a depth 150 below the surface of the dielectric substrate. If the partial holes 144 are etched to form a fold guide in dielectric substrate 100 then width 114 defines the width of the folding portion of the fold guide. This width can be altered by altering the number of rows of dots and/or the size of the dots on photomask 132 (shown in FIG. 7A).

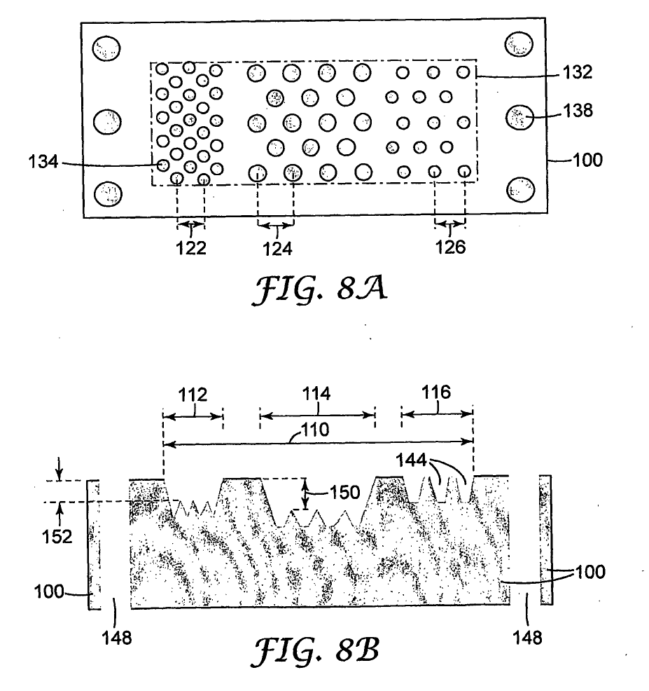

FIG. 8A shows a photomask 132 with three arrays of dots 134 and additional dots 138. Dots 134 are separated by pitches 122, 124, and 126 on the photomask. The circumference of the dots varies as well as the pitch of the dots between the arrays of dots on the photomask. The arrangement of dots 134 on photomask 132 is designed to provide a pattern for a corresponding array of holes in the photoresist applied to a dielectric substrate. The photoresist is exposed using the photomask to pattern the holes into the photoresist. The photoresist is then developed to expose areas of the dielectric substrate to be etched using known etching techniques. Again, the above photomask design is for use with negative photoresist and a reverse contrast in photomask will be required for use with positive photoresist.

FIG. 8B is cross-sectional view of part of substrate 100 showing partial holes 144 and through holes 148 formed in the dielectric substrate. In this view the differences between the pitches and circumferences of the dots on the photomask can clearly be seen in the etched dielectric substrate. The holes with the smallest pitch 122 and smallest circumference form an array with width 112 in substrate 100. These partially etched holes are connected with the areas between the holes etched to a depth 152 beneath the surface of the dielectric substrate. The holes with the small pitch 126 and smallest circumference form an array with width 116 in substrate 100. These partially etched holes are not connected as can be seen in FIG. 8B. These holes are not connected because of the small pitch of the holes when compared to the holes with smallest pitch 122. The holes with the large circumference and largest pitch 124 form an array with width 114 in substrate 100. These holes are deeper than the smaller circumference holes and are connected with the areas between the holes etched to a depth 150 beneath the surface of the dielectric substrate.

The largest circumference holes 138 extend completely through the substrate 100 as shown in FIG. 8B. FIG. 8B shows that the circumference of the holes can be used to determine how far the hole will penetrate into the substrate. The combination of circumference of the holes and pitch of the holes can be used to determine the depth of etching of the holes and any etching between the holes. Using the method of the invention, holes can be etched simultaneously partially and completely through the dielectric substrate.

As well as etching holes in the dielectric substrate, circuits can be formed on the major surface of the substrate not etched in the steps described above. Methods and apparatuses for forming metal and circuits on a dielectric substrate are well known. For example wiring can be formed over the substrate and solder resist layered over the wiring to protect the wiring.

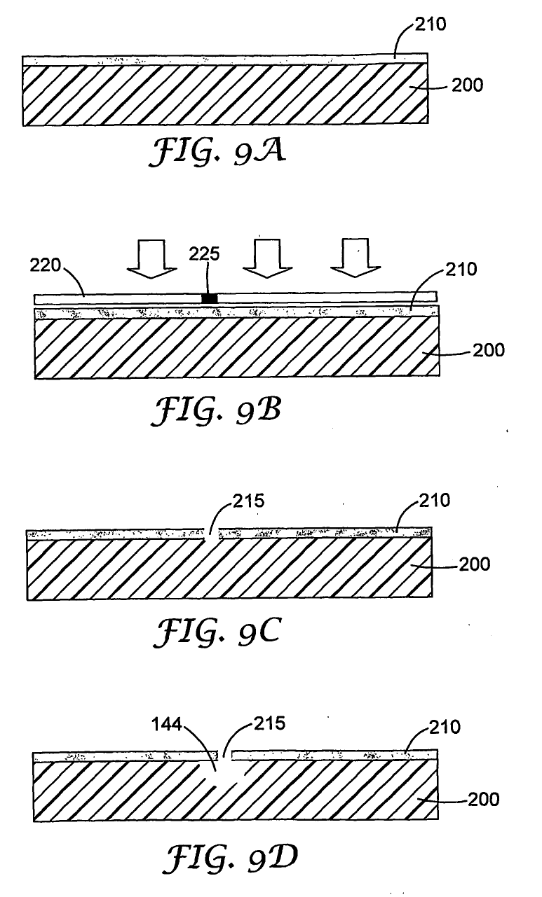

FIGS. 9A to 9D show one example of a selective chemical etching process used to create partial holes in a substrate in accordance with the invention. In this example the substrate is a polyimide of 75 microns thick. In FIG. 9A the polyimide 200 is covered by a negative photoresist 210. It should be noted that either positive or negative photoresist could be used so long as it performs correctly with the etching solutions used in the etching process. For the present example, the optimum thickness of the negative photoresist is between 20 microns and 50 microns.

Following the step of applying the photoresist 210, the photoresist 210 is exposed to actinic radiation through a photomask 220 as shown in FIG. 9B. In this example, the covered area 225 on the photomask 220 prevents the corresponding area of the underlying photoresist 210 from being exposed to the actinic radiation (shown by the arrows).

After exposing the photoresist 210, the photoresist 210 is developed as shown in FIG. 9C. Developing the photoresist 210 removes the unexposed photoresist leaving a hole 215 in the photoresist 210. It should be noted that an array of holes will be patterned in the photoresist 210 to form a fold guide but in this example, only a single hole is formed for ease of explanation.

The polyimide 200 is then etched using known chemical etching processes. The etching process forms a hole 144 in the polyimide 200 as shown in FIG. 9D. It is important to note that hole 144 does not extend completely through the polyimide 200. If hole 144 did extend completely through the polyimide, then when the solder resist layer (not shown in FIGS. 9A to 9D) is later added over the copper wiring layer (not shown in FIGS. 9A to 9D) on the second side of the polyimide 200, the solder resist will leak through hole 144 and contaminate the first side of the polyimide 200. It should also be noted that the etching process causes the sides of hole 144 to be wider than the hole 215 provided in the photoresist 210. The larger hole circumference 144 compared to the hole circumference 215 in the photoresist 210 is a feature of the etching process.

It should be noted that while hole 144 in FIG. 9D does not extend completely through the polyimide 200, it is possible to create holes that extend completely through the polyimide using the same process. In locations where it is desired to create through holes, no copper wiring is added to those locations. The lack of copper wiring in the vicinity of through holes eliminates the prior art problems of solder resist leakage and contamination. Through holes may serve as sprocket holes, tool holes, or the like.

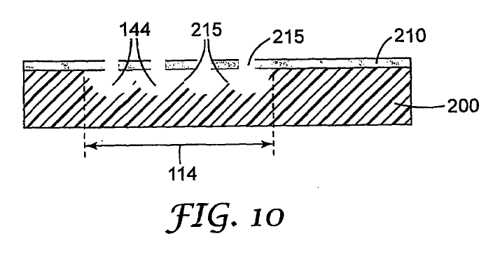

FIG. 10 is a cross-section of a polyimide 200 with an array of holes 144 formed by the selective chemical etching technique of the invention. The array of holes 144 is formed by first patterning and exposing portions of photoresist 210 through a photomask 220 with a corresponding array of dots. Again in FIG. 10, a negative photoresist 210 is used so the unexposed areas form the array of holes 215 in the photoresist 210. The polyimide 200 is then etched to form holes 144. The holes 144 in the array are spaced such that during etching of the holes, mutual etching occurs that etches the spaces between the holes thereby forming gaps 146. These sections are etched under the existing photoresist 210. The mutual etching connects the holes 144 to form the fold guide 114 in the polyimide 200. The design thickness of the unetched dielectric substrate of a fold guide will depend on a number of parameters including the substrate material and the amount of bend required of the fold guide. In exemplary embodiments the thickness of the etched portion of the fold guide substrate is about 80% of the unetched dielectric substrate thickness.

FIGS. 6A, 7A, and 8A illustrate how a photomask can be designed to provide a pattern for an array of holes in the negative photoresist. In these figures dots 134 cover areas on the photomask and virtual line 132 shows the boundary of the fold guide that will be formed on the substrate.

In a further example the etching can be performed using a strong alkaline solution. In one embodiment potassium hydroxide (KOH) is used as an etching solution for APICAL NPI 3 mil polyimide from Kaneka High-Tech Materials, Inc, Pasadena, Tex. (USA) and the polyimide etching was performed at a temperature of 93° C. using a spray pressure of 800 KPa for an etching period of 350 seconds. In general terms, setting the minimum thickness of the polyimide where the holes are formed at about 63% of the previous polyimide thickness is desirable when the hole pitch is 200 microns. In this example, an etched substrate thickness of about 63% of the unetched substrate thickness will provide a folding area for a fold guide. In this example, the optimum fold guide is formed when the thickness of the etched substrate is about 63% of the unetched substrate thickness. In other examples, different etched substrate thicknesses may be used to form fold guides. If the substrate film in this example is etched for a period of about 220 seconds, the thickness of the polyimide film where the holes are formed is about 90% of the thickness of the unetched polyimide film. In this example, etching the substrate for a shorter duration will produce holes in the substrate where the unetched substrate is a greater thickness than holes produced in longer duration etches. The size and pitch of the dots on the photomask are also related to the amount of etching that will occur during an etch duration.

It should be noted that while the holes shown in the examples are round, holes of any shape can be formed. The holes could be hexagonal for example. Also, the holes may be of the same size or of varying sizes and arranged at the same distance apart or at different distances apart within the same pre-defined location or at different pre-defined locations.

The foregoing describes the invention including preferred forms thereof. Alterations and modifications as will be obvious to those skilled in the art are intended to be incorporated in the scope hereof as defined by the accompanying claims.

1. A method of forming holes in a dielectric substrate comprising the steps of:
applying a layer of photoresist to a dielectric substrate,
exposing portions of the photoresist to actinic radiation through a photomask to form a pattern in the photoresist for an array of holes to be etched in the substrate,
developing the photoresist,
etching the dielectric substrate to form an array of holes, at least one hole extending partially through the dielectric substrate, and
removing the excess photoresist.

2. A method of forming holes in a dielectric substrate as claimed in claim 1 wherein the step of etching the dielectric substrate forms an array of holes extending partially through the dielectric substrate.

3. A method of forming holes in a dielectric substrate as claimed in claim 1 further including the steps of:
providing a photomask comprising an array of distinct dots,
exposing portions of the photoresist to actinic radiation through the photomask,
etching the dielectric substrate to form an array of holes, wherein one or both of the size and pitch of the dots on the photomask is selected so that at least two of the holes formed in the dielectric substrate after etching are connected.

4. A method of forming holes in a dielectric substrate as claimed in claim 1 wherein the array of holes is arranged to form a fold guide in the dielectric substrate.

5. A method of forming holes in a dielectric substrate as claimed in claim 4 wherein the thickness of the etched portion of the fold guide substrate is about 80% of the unetched dielectric substrate thickness.

6. A dielectric substrate comprising:
at least one array of holes wherein at least one hole is partially etched into the dielectric substrate,
wiring formed on the dielectric substrate, and
solder resist layered over the wiring to protect the wiring.

7. A dielectric substrate as claimed in claim 6 wherein the array of holes is partially etched in the dielectric substrate.

8. A dielectric substrate as claimed in claim 6 wherein at least two holes in the plurality of holes in the substrate are connected after being etched.

9. A dielectric substrate as claimed in claim 6 wherein the array of holes is arranged to form a fold guide in the dielectric substrate.

10. A dielectric substrate as claimed in claim 9 wherein the thickness of the etched portion of the fold guide substrate is about 80% of the unetched dielectric substrate thickness.

11. A dielectric substrate as claimed in claim 6 wherein the dielectric substrate may further comprise at least one integrated circuit.

12. A method of forming holes in a dielectric substrate comprising the steps of:
applying a layer of photoresist to a dielectric substrate,
exposing portions of the photoresist to actinic radiation through a photomask to form a pattern in the photoresist for a plurality of holes comprising at least one array of holes to be etched in the substrate,
developing the photoresist,
etching the dielectric substrate to form an array of holes extending partially through the dielectric substrate and at least one hole extending completely through the dielectric substrate, and
removing the excess photoresist.

13. A method of forming holes in a dielectric substrate as claimed in claim 12 further including the steps of:
providing a photomask comprising an array of distinct dots,
exposing portions of the photoresist to actinic radiation through the photomask,
etching the dielectric substrate to form an array of holes, wherein one or both of the size and pitch of the dots on the photomask is selected so that at least two of the holes formed in the dielectric substrate after etching are connected.

14. A method of forming holes in a dielectric substrate as claimed in claim 12 wherein at least one array of holes is arranged to form a fold guide.

15. A method of forming holes in a dielectric substrate as claimed in claim 14 wherein the thickness of the etched portion of the fold guide substrate is about 80% of the unetched dielectric substrate thickness.

16. A dielectric substrate comprising:
at least one array of holes partially etched into the dielectric substrate,
at least one hole etched completely through the dielectric substrate,
wiring formed on the dielectric substrate, and
solder resist layered over the wiring to protect the wiring.

17. A dielectric substrate as claimed in claim 16 wherein a plurality of holes is formed completely through the dielectric substrate.

18. A dielectric substrate as claimed in claim 16 wherein at least two holes in the array of holes partially etched in the dielectric substrate are connected after being etched.

19. A dielectric substrate as claimed in claim 16 wherein the array of holes partially etched in the dielectric substrate is arranged to form a fold guide in the dielectric substrate.

20. A dielectric substrate as claimed in claim 19 wherein the thickness of the etched portion of the fold guide substrate is about 80% of the unetched dielectric substrate thickness.
